(19) United States
(12) Patent Application Publication
(10) Pub. No.: US 2008/0017876 A1
(43) Pub. Date: Jan. 24, 2008

(54) SI-SUBSTRATE AND STRUCTURE OF OPTO-ELECTRONIC PACKAGE HAVING THE SAME

(76) Inventor: Hung-Yi Lin, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/612,486

(22) Filed: Dec. 19, 2006

(30) Foreign Application Priority Data
Jul. 24, 2006 (TW) 095126950

(51) Int. Cl. H01L 33/00

(52) U.S. Cl. 257/98

(57) ABSTRACT

Disclosed herein is a structure of an opto-electronic package having a Si-substrate. Si-substrates are manufactured in batch utilizing micro-electromechanical processes or semiconductor processes, so that these Si-substrates are made with great precision and full of varieties. Based on the material characteristic of the Si-substrate, and the configuration of the components, such as the connecters, opto-electronic devices, depressions, solder bumps, etc., the present invention can improve the optical effect, the heat dissipating effect, and the reliability of the structure of opto-electronic package, and simplifies the complexity of the structure of opto-electronic package.

### BACKGROUND OF THE INVENTION

1. Field of the Invention

The present invention generally relates to the field of opto-electronic package structures, and more particularly, to an opto-electronic package structure formed by the micro-electromechanical processes or the semiconductor processes.

2. Description of the Prior Art

In recent years, a new application field of high illumination light emitting diodes (LEDs) has been developed. Different from a common incandescent light, a cold illumination LED has the advantages of low power consumption, long device lifetime, no idling time, and quick response speed. In addition, since the LED also has the advantages of small size, vibration resistance, suitability for mass production, and ease of fabrication as a tiny device or an array device, it has been widely applied in display apparatuses and indicating lamps used in information, communication, and consumer electronic products. The LEDs are not only utilized in outdoor traffic signal lamps or various outdoor displays, but are also very important components in the automotive industry. Furthermore, the LEDs work well in portable products, such as cellular phones and as backlights of personal data assistants. These LEDs have become necessary key components in the highly popular liquid crystal displays because they are the best choice when selecting the light source of the backlight module.

Please refer to FIG. 1 and FIG. 2. FIG. 1 is a schematic top view diagram showing a prior art surface mount device (SMD) LED package structure 10, and FIG. 2 is a cross section diagram illustrating the prior art SMD LED package structure 10 along 1-1 ′ line shown in FIG. 1. As shown in FIG. 1 and FIG. 2, an SMD LED package structure 10 comprises a cup-structure substrate 12, a lead frame 14, an opto-electronic device 16, conducting wires 18 and 20, and a sealant 22. As a semiconductor device comprising a positive electrode and a negative electrode (not shown), the opto-electronic device 16 is illuminated by receiving power from an external voltage source and connected to the lead frame 14 by the conducting wires 18 and 20. Situated in the cup-structure substrate 12, the lead frame 14 is extended to the outer surface of the cup-structure substrate 12, which will be electrically connected to a printed circuit board (PCB) 24.

In order to construct the prior art LED package 10, the cup-structure substrate 12 should be completed first, and then the sealant 22 covers the opto-electronic device 16 by means of molding or sealant injection. After the construction of the prior art LED package 10 is completed, at least a surface mounting process is performed to mount the LED packages 10 on the PCB 24 individually. As a result, it is almost impossible to produce the LED packages 10 in batch, and the manufacturing process of the electronic products is too complicated and tedious. As applied in a LED package 10 with high power, the cup-structure substrate 12 of the opto-electronic device 16 is unavoidably overheated, which may eventually result in a reduction of light intensity or failure of the entire device. Due to the significantly large volume of the single LED package 10 and the heat radiating demand required by a LED package 10 with high power, the designed size and the heat dissipating efficiency of the whole LED package 10 are greatly limited.

### SUMMARY OF THE INVENTION

It is the primary object of the present invention to provide an opto-electronic package structure having a Si-substrate. Accordingly, the present invention can improve the optical effect, the heat dissipating effect, and the reliability of the opto-electronic package structure, the opto-electronic package structure can be manufactured in batch, and the complexity of the opto-electronic package structure can be simplified.

According to the claimed invention, an opto-electronic package structure having a Si-substrate is disclosed. The opto-electronic package structure includes a Si-substrate having a top surface, a plurality of connecters, and at least an opto-electronic device positioned on the top surface of the Si-substrate. The connecters are a layer covering the top surface of the Si-substrate, and the opto-electronic device is electrically connected to the connecters.

Since the Si-substrates can be produced in a batch system utilizing micro-electromechanical processes or semiconductor processes, these Si-substrates are made with great precision and full of varieties. According to the characteristics of Si-substrate and the arrangement of the components, such as the connecters, the opto-electronic device, the cup-structure and the flip-chip bump on Si-substrate, the present invention can simplify the complexity of the components in the opto-electronic package structure, and increase the optical effect, the heat-dissipating effect and the packaging reliability of the opto-electronic package structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view diagram showing a prior art surface mount device (SMD) LED package structure.

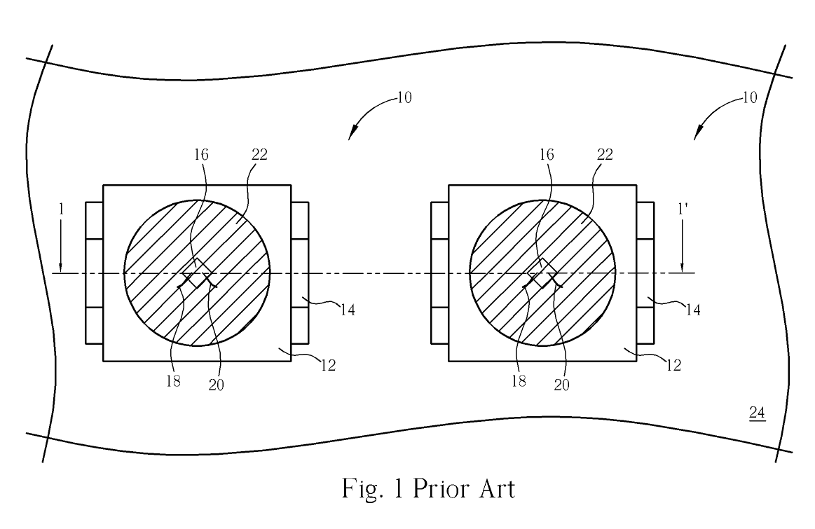

FIG. 2 is a cross section diagram illustrating the prior art SMD LED package structure along 1-1′ line shown in FIG. 1.

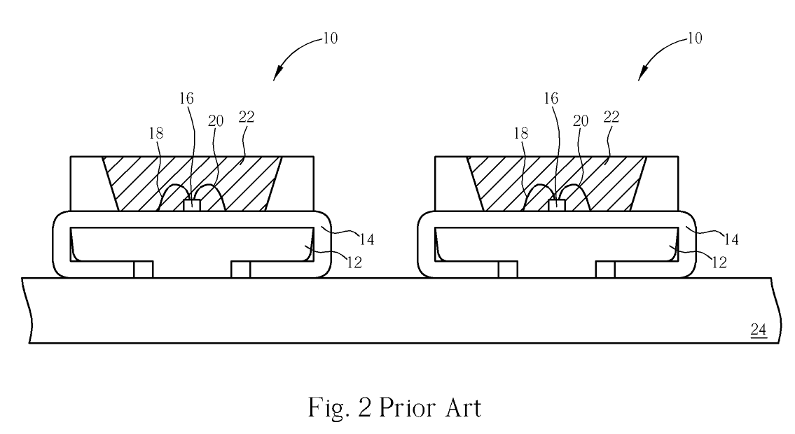

FIG. 3 is a schematic cross-sectional diagram illustrating an opto-electronic package structure having a Si-substrate according to a first preferred embodiment of the present invention.

FIG. 4 is a schematic top view of the opto-electronic package structure shown in FIG. 3.

FIG. 5 is a schematic diagram illustrating an opto-electronic package structure having a Si-substrate according to a second preferred embodiment of the present invention.

FIG. 6 is a cross-sectional schematic diagram illustrating the opto-electronic package structure along line 5-5′ shown in FIG. 5.

FIG. 7 is a cross-sectional schematic diagram illustrating an opto-electronic package structure having a Si-substrate according to a third preferred embodiment of the present invention.

FIG. 8 is a cross-sectional schematic diagram illustrating an opto-electronic package structure having a Si-substrate according to a fourth preferred embodiment of the present invention.

### DETAILED DESCRIPTION

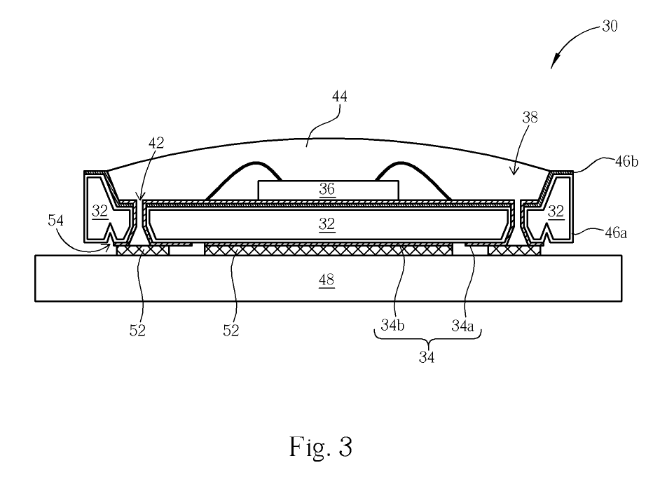

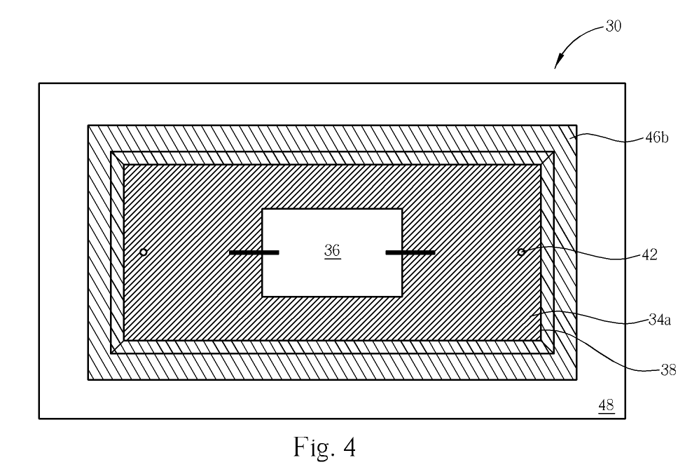

Please refer to FIG. 3 and FIG. 4. FIG. 3 is a schematic cross-sectional diagram illustrating an opto-electronic package structure 30 having a Si-substrate 32 according to a first preferred embodiment of the present invention, and Fig.4 is a schematic top view of the opto-electronic package structure 30 shown in FIG. 3. It is to be understood that the drawings are not drawn to scale and are used only for illustration purposes. As shown in FIG. 3 and FIG. 4, an opto-electronic package structure 30 includes a Si-substrate 32, a plurality of connecters 34 and at least an opto-electronic device 36. The material of the Si-substrate 32 includes polysilicon, amorphous silicon or single-crystal silicon. In addition, the Si-substrate 32 can be a rectangle silicon chip or a circular silicon chip, and can include integrated circuits or passive components therein. The Si-substrate 32 has a top surface and a bottom surface. A cup-structure 38 can be included on the top surface of the Si-substrate 32 for having a capacity of the opto-electronic device 36. The Si-substrate 32 can control the optical effect of the opto-electronic package structure 30 by means of some factors, such as the position of the cup-structure 38, the hollow depth of the cup-structure 38, the hollow width of the cup-structure 38 and the sidewall shape of the cup-structure 38. A plurality of electric-conducting holes 42 can be included in the Si-substrate 32, and each electric-conducting hole 42 penetrates through the Si-substrate 32 from the top surface to the bottom surface.

The connecters 34 include a plurality of substrate-penetrating electric-conducting wires 34a and at least a heat-conducting wire 34b. The substrate-penetrating electric-conducting wires 34a and the heat-conducting wire 34b can be formed in the meantime utilizing a micro-electromechanical process or a semiconductor process, such as a plating process or a deposition process. For forming the substrate-penetrating electric-conducting wires 34a and the heat-conducting wire 34b, a metal layer is formed on the top surface of the Si-substrate 32, the bottom surface of the Si-substrate 32 and sidewalls of the electric-conducting holes 42 first. Thereafter, the substrate-penetrating electric-conducting wires 34a and the heat-conducting wire 34b are separated by means of an etching process so that the substrate-penetrating electric-conducting wires 34a and the heat-conducting wire 34b do not electrically connect to each other. Each substrate-penetrating electric-conducting wire 34a extends from the top surface of the Si-substrate 32 to the bottom surface of the Si-substrate 32 through at least one of the electric-conducting holes 42. The heat-conducting wire 34b covers portions of the bottom surface of the Si-substrate 32, and is preferably located in a position corresponding to the opto-electronic device 36. Specifically speaking, the heat-conducting wire 34b can be a flat metal layer having large area, and each substrate-penetrating electric-conducting wire 34a can be a flat metal layer having large area or a metal circuit layer having circuit therein.

The opto-electronic device 36 can be a light-emitting component or a photo sensor, such as a light emitting diode (LED), a photo diode, a digital micromirror device (DMD), or a liquid crystal on silicon (LCOS), but is not limited to those devices. The opto-electronic device 36 can be fixed onto the top surface of the Si-substrate 32 by a fixing gel. Furthermore, the positive electrode and negative electrode of the opto-electronic device 36 are then connected individually to the positive electrode terminal and the negative electrode terminal defined on the substrate-penetrating electric-conducting wires 34a, using a wire bonding technique or a flip-chip technique.

In addition to above-mentioned components, the opto-electronic package structure 30 of the present invention can further include a packaging material layer 44, an insulation layer 46a and an optical film 46b. The packaging material layer 44 is composed of mixtures containing resin, wavelength converting materials, fluorescent powder, and/or light-diffusing materials. Next, the packaging material layer 44 is packaged onto the substrate 10 by a molding or sealant injection method so as to increase the product reliability of the opto-electronic package structure 30, and to control the optical effect of the opto-electronic device 36. The optical film 46b can be a coat having a high refractive index located on the bottom and the sidewall of the cup-structure 38, and it can further increase the light quantity propagating from the opto-electronic package structure 30 in combination with the cup-structure 38.

Through the substrate-penetrating electric-conducting wires 34a on the bottom surface of the Si-substrate 32, the opto-electronic package structure 30 can be connected onto a printed circuit board 48 by means of surface mounting. The printed circuit board 48 can be a glass fiber reinforced polymeric material, such as ANSI Grade. FR-1, FR-2, FR-3, FR-4 or FR-5, or a metal core printed circuit board. According to its concrete mounting process, a solder paste can first be formed on the surface of the printed circuit board 48 to be a metal connecting layer 52. The metal connecting layer 52 corresponds to and connects with the substrate-penetrating electric-conducting wires 34a and the heat-conducting wire 34b positioned on the bottom surface of the opto-electronic package structure 30. Therefore, the opto-electronic package structure 30 can electrically connect to the printed circuit board 48 through the substrate-penetrating electric-conducting wires 34a and the metal connecting layer 52. On the other hand, in order to form a structure having different conducting paths for heat and for electrons, the produced heat of the opto-electronic device 36 can be transmitted to the surroundings through the heat conducting path constituted by the Si-substrate 32, the heat-conducting wire 34b, the metal connecting layer 52 and the printed circuit board 48. Once the metal connecting layer 52 is squeezed or the position of the metal connecting layer 52 deviates, the metal connecting layer 52 might contact with other components, and cause a short circuit. In order to prevent the metal connecting layer 52 from contacting with other components, the bottom surface of the Si-substrate 32 in the present invention can further include a plurality of trenches 54 to receive the unnecessary solder paste. Thus, the occurring probability of the short between the metal connecting layer 52 and other components can be easily reduced without using the expensive wafer having a high resistance.

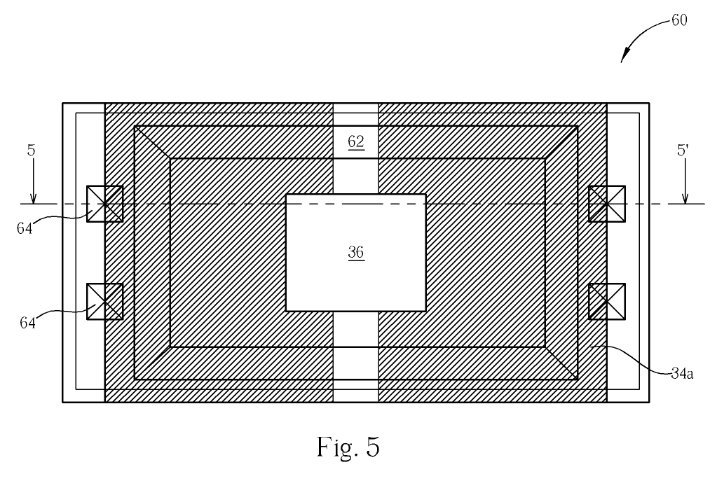

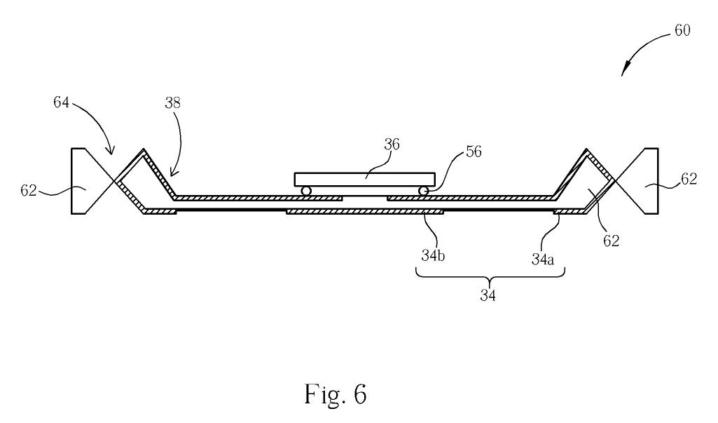

The opto-electronic package structure of the present invention can be arranged in other forms according to other embodiments. Please refer to FIG. 5 and FIG. 6. Fig.5 is a schematic diagram illustrating an opto-electronic package structure 60 having a Si-substrate 62 according to a second preferred embodiment of the present invention, and Fig.6 is a cross-sectional schematic diagram illustrating the opto-electronic package structure 60 along line 5-5′ shown in FIG. 5, wherein like number numerals designate similar or the same parts, regions or elements. As shown in FIG. 5 and FIG. 6, an opto-electronic package structure 60 includes a Si-substrate 62, a plurality of connecters 34 and at least an opto-electronic device 36. The material of the Si-substrate 62 includes polysilicon, amorphous silicon or single-crystal silicon, and can include integrated circuits or passive components therein. A cup-structure 38 is included in the top surface of the Si-substrate 62 so as to contain the opto-electronic device 36 therein.

The connecters 34 include a plurality of substrate-penetrating electric-conducting wires 34a and can further include at least a heat-conducting wire 34b. In order to form the substrate-penetrating electric-conducting wires 34a and the heat-conducting wire 34b simultaneously, a metal layer is first formed on the top surface of the Si-substrate 62, the bottom surface of the Si-substrate 62 and sidewalls of the electric-conducting holes 64 utilizing a plating process or a deposition process. Next, the substrate-penetrating electric-conducting wires 34a and the heat-conducting wire 34b are separated by means of an etching process so that the substrate-penetrating electric-conducting wires 34a and the heat-conducting wire 34b do not electrically connect to each other. Each substrate-penetrating electric-conducting wire 34a extends from the top surface of the Si-substrate 62 to the bottom surface of the Si-substrate 62 through at least one of the electric-conducting holes 64. The heat-conducting wire 34b covers portions of the bottom surface of the Si-substrate 62, and is preferably located in a position corresponding to the opto-electronic device 36. In application, the heat-conducting wire 34b can be a flat metal layer having large area, and each substrate-penetrating electric-conducting wires 34a can be a flat metal layer having large area or a metal circuit layer having circuit therein.

The positive electrode and negative electrode of the opto-electronic device 36 can first be connected individually to the positive electrode terminal and the negative electrode terminal defined on the substrate-penetrating electric-conducting wires 34a through a plurality of solder bumps 56. Subsequently, the positive electrode and negative electrode of the opto-electronic device 36 are connected to a printed circuit board (not shown in the figure) through the substrate-penetrating electric-conducting wires 34a positioned on the bottom surface of the Si-substrate 62. Additionally, in order to form a structure having different conducting paths for heat and for electrons, the opto-electronic device 36 can transmit the produced heat to the surroundings through the heat conducting path constituted by the Si-substrate 62, the heat-conducting wire 34b and the printed circuit board.

It should be noticed that the electric-conducting holes 42 of the first preferred embodiment penetrate parts of the Si-substrate 32 positioned under the cup-structure 38, and the electric-conducting holes 64 of this embodiment penetrate parts of the Si-substrate 32 positioned around the cup-structures 38. Because the electric-conducting holes 64 of this embodiment are located around the cup-structure 38, the surface in the bottom and in the sidewall of the cup-structure 38 can be completely covered with the substrate-penetrating electric-conducting wires 34a of the connecters 34. According to this arrangement, the substrate-penetrating electric-conducting wires 34a can promote light effect, electric effect and heat effect in the meantime. In addition to providing an electric conducting path, the metal of the substrate-penetrating electric-conducting wires 34a can also provide excellent reflecting effect, and increase an optical benefit. The substrate-penetrating electric-conducting wires 34a having metal material can even directly function as an optical film. Furthermore, the substrate-penetrating electric-conducting wires 34a formed by metal material has a great heat transfer coefficient, so the heat generated in the opto-electronic package structure 60 can be dissipated easily.

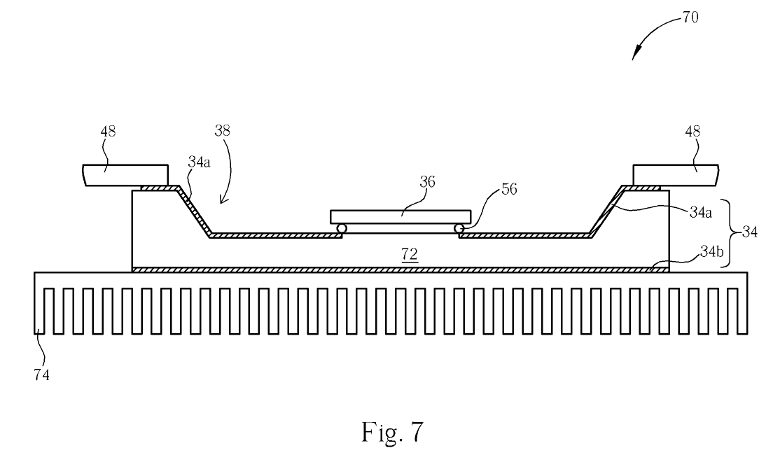

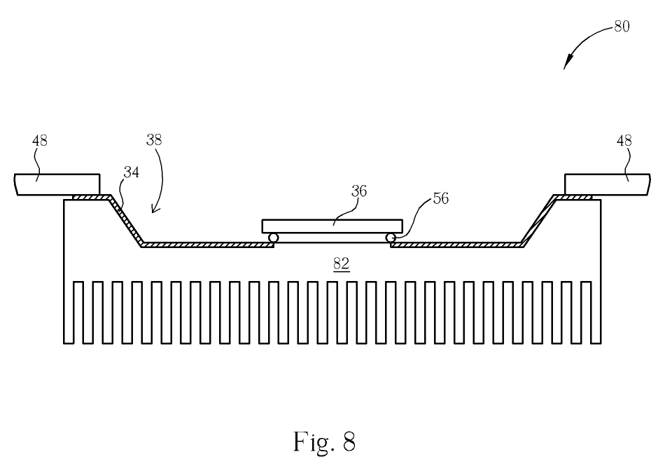

Please refer to FIG. 7 and FIG. 8 showing other embodiments of the present invention. FIG. 7 is a cross-sectional schematic diagram illustrating an opto-electronic package structure 70 having a Si-substrate 72 according to a third preferred embodiment of the present invention, and FIG. 8 is a cross-sectional schematic diagram illustrating an opto-electronic package structure 80 having a Si-substrate 82 according to a fourth preferred embodiment of the present invention, wherein like number numerals designate similar or the same parts, regions or elements.

As shown in FIG. 7, an opto-electronic package structure 70 includes a Si-substrate 72, a plurality of connecters 34 and at least an opto-electronic device 36. A cup-structure 38 is included in the top surface of the Si-substrate 72 so as to contain the opto-electronic device 36 therein.

The connecters 34 can be a flat metal layer having large area or a metal circuit layer having circuits therein. The connecters 34 include a plurality of substrate-penetrating electric-conducting wires 34a for conducting electricity and at least a heat-conducting wire 34b for conducting heat. The positive electrode and negative electrode of the opto-electronic device 36 can first be connected individually to the positive electrode terminal and the negative electrode terminal defined on the substrate-penetrating electric-conducting wires 34a through a plurality of solder bumps 56. Subsequently, the positive electrode and negative electrode of the opto-electronic device 36 are connected to a printed circuit board 48 through the substrate-penetrating electric-conducting wires 34a. It is worthy of note that the heat-conducting wire 34b positioned on the bottom surface of the opto-electronic package structure 70 can be further connected to at least a heat-dissipating device 74, such as a fin. As a result, the opto-electronic device 36 can transfer the generated heat to the surrounding via the Si-substrate 72, the heat-conducting wire 34b and the heat-dissipating device 74, and form a structure having different conducting paths for heat and for electrons.

As shown in FIG. 8, an opto-electronic package structure 80 includes a Si-substrate 82, a plurality of connecters 34 and at least an opto-electronic device 36. A cup-structure 38 is included in the top surface of the Si-substrate 82 so as to contain the opto-electronic device 36 therein. The connecters 34 can be a flat metal layer having large area or a metal circuit layer having circuit therein, and used for electrically connection, heat conduction and light benefit. The positive electrode and negative electrode of the opto-electronic device 36 can be connected individually to the positive electrode terminal and the negative electrode terminal defined on the connecters 34 through a plurality of solder bumps 56, and then are connected to a printed circuit board 48 through the connecters 34. Because the Si-substrate 82 can be produced by the micro-electromechanical processes or the semiconductor processes that are developed technology, the Si-substrate 82 can include a fin structure on the bottom surface of the opto-electronic package structure 80. As a result, the opto-electronic device 36 can directly dissipate the generated heat through the Si-substrate 72, and form a great heat-dissipating structure.

After all components of the above-mentioned opto-electronic package structure are completed, the Si-substrates can be separated from each other by means of a wafer sawing process, and each opto-electronic package structure is electrically connected to the corresponding printed circuit board through the connecters of each Si-substrate.

Because the present invention chooses the Si-substrate to form the opto-electronic package structure, and the heat transfer coefficient of silicon material is quite large, the heat-dissipating effect of the opto-electronic package structure can be increased. In addition, since silicon and an LED are both made from semiconductor materials, the coefficient of thermal expansion (CTE) of silicon is approximate to the CTE of the LED. Therefore, using silicon to form the packaging substrate can increase the reliability of the produced opto-electronic package structure.

Furthermore, the opto-electronic package structure having the Si-substrate can be made in a batch system utilizing micro-electromechanical processes or semiconductor processes. According to this arrangement, the connecters can promote light effect, electric effect and heat effect in the meantime. In addition to providing electric conducting path, the metal characteristic of the connecters can also provide excellent reflecting effect, and increase an optical benefit. Even, the connecters having metal material can directly function as an optical film. Furthermore, the connecters formed by metal material has a great heat transfer coefficient, so the heat generated in the opto-electronic package structure can be dissipated easily. As a result, the present invention can simplify the complexity of the components in the opto-electronic package structure, and increase the optical effect, the heat-dissipating effect and the packaging reliability of the opto-electronic package structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An opto-electronic package structure having a silicon-substrate (Si-substrate), comprising:
a Si-substrate having a top surface;
a plurality of connecters, being a layer covering the top surface of the Si-substrate; and
at least an opto-electronic device positioned on the top surface of the Si-substrate, and electrically connected to the connecters.

2. The opto-electronic package structure of claim 1, wherein the top surface of the Si-substrate comprises a cup-structure, and the opto-electronic device is positioned in the cup-structure.

3. The opto-electronic package structure of claim 2, wherein the connecters cover the bottom of the cup-structure.

4. The opto-electronic package structure of claim 2, wherein the connecters cover the bottom and the sidewall of the cup-structure.

5. The opto-electronic package structure of claim 1, wherein the connecters contact with a fin below.

6. The opto-electronic package structure of claim 1, wherein the Si-substrate comprises a bottom surface, and the bottom surface of the Si-substrate comprises a fin structure.

7. The opto-electronic package structure of claim 1, wherein each of the connecters is electrically connected to a printed circuit board.

8. The opto-electronic package structure of claim 1, wherein each of the connecters is a metal layer.

9. The opto-electronic package structure of claim 1, wherein the opto-electronic device comprises a light emitting diode (LED).
